(19) United States
(12) Patent Application Publication
(10) Pub. No.: US 2026/0068577 A1
(43) Pub. Date: Mar. 5, 2026

(54) STAGE APPARATUS OF SIDE TRACK BUFFER AND SEMICONDUCTOR PROCESS DEVICE COMPRISING THE SAME

(71) Applicant: Justem Co., Ltd., Yongin-si (KR)

(72) Inventors: Young Jin LIM, Yongin-si (KR); Yong Jin KIM, Yongin-si (KR); Jeong Hun YOUK, Suwon-si (KR); Soon Taek JEONG, Suwon-si (KR)

(21) Appl. No.: 19/019,838

(22) Filed: Jan. 14, 2025

(30) Foreign Application Priority Data
Sep. 5, 2024 (KR) 10-2024-0120828
Dec. 30, 2024 (KR) 10-2024-0200256

(51) Int. Cl. H01L 21/67

(52) U.S. Cl. CPC H01L 21/67017

(57) ABSTRACT

The present invention relates to a stage device of a side track buffer, which allows an inert gas to flow through a semiconductor process facility, and a semiconductor process facility including the same. The stage device of the side track buffer includes a supply part installed at one side of a first base of a first module unit to supply the inert gas, a first flow control part configured to control a flow rate of the inert gas, and a discharge part configured to discharge the inert gas. Thus, the present invention provides may provide an effect of improving productivity and process performance of the semiconductor process device by detecting a temperature of the inert gas discharged from the semiconductor process device and humidity of the semiconductor process facility to individually control inflow and discharge amounts of inert gas in the plurality of semiconductor process devices.

### CROSS-REFERENCE TO RELATED APPLICATIONS

This U.S. non-provisional patent application claims priority under 35 U.S.C. § 119 of Korean Patent Application Nos. 10-2024-0120828, filed on Sep. 5, 2024 and 10-2024-0200256, filed on Dec. 30, 2024, the entire contents of which are hereby incorporated by reference.

### FIELD OF THE INVENTION

The present invention disclosed herein relates to a stage apparatus of a side track buffer and a semiconductor processing device including the same, and more particularly, to a stage apparatus of a side track buffer that allows an inert gas to flow into the side track buffer and a semiconductor processing device including the same.

### BACKGROUND ART

A silicon wafer may become contaminated on a surface thereof by various contaminants during a wafer manufacturing process or a semiconductor process such as exposure, deposition, and etching for element integration. To prevent such contamination and improve a process speed, the silicon wafer moves in a state in which a plurality of silicon wafers are laminated in a cassette during the wafer manufacturing process or the semiconductor process or is packaged and shipped in the state in which the plurality of silicon wafers are laminated.

In general, the wafer widely used as a material for manufacturing a semiconductor element is referred to as a single-crystal silicon thin plate made using polycrystalline silicon as a raw material.

The semiconductor element is manufactured by sequentially applying a number of unit processes to the water that is a target substrate. Here, the wafer is accommodated in a front opening unified POD (FOUP) (hereinafter, referred to a ‘FOUP’) to prevent contamination by external particles and then is transferred by a transfer system that connects manufacturing facilities for each unit process.

Particularly, a ceiling transfer system disposed on a ceiling of a semiconductor fabrication plate (FAB) that is a clean room for manufacturing a semiconductor element to automatically transfer the FOUP as a transfer system is being widely used.

When a substrate that is completely processed in the facilities that perform the unit processes for manufacturing the semiconductor element is accommodated in the FOUP and then discharged to a load port LP adjacent to each facility, a ceiling transfer device disposed at an upper portion of each facility accommodates the FOUP to transfer the FOUP to a subsequent process facility in which a subsequent unit process is performed.

The ceiling transfer device is constituted by a transfer rail installed on the ceiling of the semiconductor FAB, a transfer vehicle that protects the FOUP from the outside while moving along the transfer rail, and a station that is a target to be transferred and stacked.

The station include a load port added to the unit process facility for manufacturing the semiconductor element, and a side track buffer STB and an under track buffer UTB, which are respectively provided at side and lower portions of the transfer rail to store the FOUP.

Recently, as the semiconductor device structure becomes more miniaturized, an influence of moisture, oxygen, chemical components, etc., has become a greater issue, and as a result, it has been proposed to replace the inside of a transfer chamber by an N₂ (nitrogen) gas that is an inert gas to perform transferring of a wafer under an N₂ atmosphere.

In this case, to suppress running costs by reducing consumption of the N₂ gas, the N₂ gas is circulated while passing through a filter due to needs to maintain internal cleanliness while reducing the supply of the fresh N₂ gas.

For example, it may be used to store the semiconductor substrate such as a substrate without a container, or a substrate disposed in the container such as the FOUP, but in order to maintain cleanliness inside a stocker, a purge gas may be provided into the stocker to prevent contamination, and it is necessary to improve the cleanliness of the container and the stocker, but there is a limitation in that a flow rate in the conventional FOUP and resultant humidity are not controlled, and monitoring of the humidity is not controlled.

In addition, there is a limitation in that the humidity control is insufficient because a time taken to allow the internal humidity value of the FOUP to decrease during the purging of the inert gas is very long, and a maximum allowable decrease in humidity is around 5%. In addition, there is a limitation in that environmental safety standards are not insufficient due to the inert gas leaking out through an opening of a door of the FOUP.

A device for performing a semiconductor wafer processing process is constituted by a processing module and a transfer module for transferring the wafer, and the transfer module includes a stocker, an overhead shuttle (OHS), an overhead hoist transport (OHT), an automated guided vehicle (AGV), and a rail guided vehicle (RGV).

All of the transport modules are aimed to reduce an initial investment burden on users, reduce the running costs so as to improve price competitiveness, prevent the contamination during the wafer transfer, and improve product yield.

Particularly, the side track buffer (STB) is a storage space which is defined in a side surface of the OHT running rail, and in which the processed FOUP is stored. The FOUP prevents external air from being in contact with the storage container for storing and transferring the wafer to improve yield of the wafer.

However, if the wafer is loaded into the FOUP while a process gas used during the wafer processing remains on a surface of the wafer, precision processing becomes difficult, secondary contamination occurs between the wafers, and the wafer transfer module becomes contaminated by fume of the process gas remaining inside the FOUP to cause deterioration in performance of the facility.

Thus, a purge device has been developed to remove the process gas inside the FOUP. A typical conventional purge device related to the purge device is a separate component added between an operating module and the transfer module to remove the process gas inside the FOUP and has a limitation in that a process is added.

Particularly, if the process gas remains inside the FOUP during the processing process for the plurality of wafers, there is an inconvenience of having to continuously remove the process gas through the conventional purge device. Furthermore, as the process for removing the process gas is added, a production time for creating the semiconductor devices increases.

To improve the limitations, a semiconductor wafer manufacturing system that supplies the inert gas to the FOUP mounted on the side track buffer has been proposed, but there is a limitation in that a specific configuration for removing or discharging the process gas inside the FOUP is insufficient.

Particularly, the FOUP and the side track buffers are components that transfer and temporarily store the wafers and also serve to improve the yield of the wafer by blocking the contact with the external air.

However if the wafer is loaded into the FOUP while the process gas used during the wafer processing remains on the surface of the wafer, the precision processing becomes difficult, the secondary contamination occurs between the wafers, and the wafer transfer module becomes contaminated by the fume of the process gas remaining inside the FOUP to cause deterioration in performance of the facility.

Thus, a purge device has been developed to remove the process gas inside the FOUP. A typical conventional purge device related to the purge device is a separate component added between an operating module and the transfer module to remove the process gas inside the FOUP and has a limitation in that a process is added.

The humidity is an important factor in the storage of the wafers after the processing. Particularly, as the semiconductor elements become more advanced, the humidity has a significant impact on an occurrence of defects in production of high-quality products.

For this reason, the humidity control, which affects the occurrence of the defects in the semiconductor elements, is important, but since it is not easy to control the entire humidity of the semiconductor FAB, there is a need to control the humidity only inside the front opening unified pod (FOUP) in which the wafers are stored in units of sheets of 25 to 26.

However, such the conventional technologies only use nitrogen for purging and does not include any configuration for controlling the humidity related to the occurrence of the defects in semiconductor elements, and thus, there is a need for the improvement.

### PRIOR ART DOCUMENT

### Patent Document

(Patent Document 1) Korean Patent Publication No. 10-2023-0103841 (July 7, 2023)

(Patent Document 2) Korean Patent Registration No. 10-2506296 (March 3, 2023)

(Patent Document 3) Korean Patent Publication No. 10-2023-0031153 (March 7, 2023)

### SUMMARY OF THE INVENTION

To solve the above-mentioned limitations, the present invention provides a stage device of a side track buffer capable of improving production performance and process performance of a semiconductor process device by detecting a temperature of an inert gas discharged from the semiconductor process device and humidity of a semiconductor process facility to individually control an inflow and discharge amount of inert gas in a plurality of semiconductor process devices, and a semiconductor process device including the same.

The present invention also provides a stage device of a side track buffer capable of improving semiconductor production yield by detachably installing a second module unit as a variable discharge module to a second module unit to individually control a discharge mount of inert gas injected into a FOUP through a supply nozzle of a semiconductor process device such as an STB for each FOUP, and a semiconductor process device including the same.

The present invention also provides a stage device of a side track buffer which includes a second base, a second flow control part, and a second discharge control part as a second module unit to detachably install the second module unit of a variable discharge module to control a discharge amount of inert gas according to an injection amount of inert gas in the second module unit and individually control the discharge amount of inert gas by receiving an electronic signal when injecting different amounts of inert gas for each FOUP at a flow rate of about 5 slm to about 50 slm, and a semiconductor process device including the same.

The present invention also provides a stage device of a side track buffer which includes a connection piece, a connection groove, and a connection protrusion as a connection unit to attach and detach a variable discharge module by using a connection unit of a joint block, thereby individually controlling a flow rate of a gas in a plurality of FOUPs, and a semiconductor process device including the same.

According to an embodiment of the present invention, a stage device of a side track buffer, which allows an inert gas to flow through the side track buffer, includes: a supply part (120) installed at one side of a first base of a first module unit (100) to supply the inert gas; a first flow control part (130) installed at one side of the supply part (120) to control a flow rate of the inert gas; a filter part (140) connected to the first flow control part (130) to filter the inert gas; and a discharge part (170) installed at the other side of the first base of the first module unit (100) to discharge the inert gas.

The stage device may further include a second module unit (200) detachably installed at one side of the first module unit (100) to control the discharge of the inert gas.

The second module unit (200) may include: a second base coupled to one end of the first base of the first module unit (100); a second flow control part installed at one side of the second base to control a discharge amount of inert gas; and a second discharge control part installed at the other side of the second base to control whether to discharge the inert gas.

The stage device may further include a connection unit (300) installed between the first module unit (100) and the second module unit (200) to connect the first base to the second base so as to be attached to and detached from each other.

The connection unit (300) may include: a connection piece configured to couple and connect the first base to the second base; a first connection groove which is recessed in one end of the connection piece and to which the first base is coupled; a second connection groove which is recessed in the other end of the connection piece and to which the second base is coupled; a first connection protrusion protruding from one end of the connection piece and coupled to the first base; and a second connection protrusion protruding from the other end of the connection piece and coupled to the second base.

The connection unit (300) may further include: a first fixing piece installed to be coupled to the first connection protrusion to fix the first base and the connection piece; and a second fixing piece installed to be coupled to the second connection protrusion to fix the second base and the connection piece.

According to another embodiment of the present invention, a semiconductor process device provided with the stage device of the side track buffer disclosed in the present invention.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view illustrating a configuration of a typical semiconductor process device;

FIG. 2 is a view illustrating a configuration of a stage device of a side track buffer according to an embodiment of the present invention;

FIG. 3 is a perspective view illustrating the stage device of the side track buffer according to an embodiment of the present invention;

FIG. 4 is an exploded perspective view illustrating the stage device of the side track buffer according to an embodiment of the present invention;

FIG. 5 is a view illustrating a coupling state after coupling the stage device of the side track buffer according to an embodiment of the present invention; and

FIG. 6 is a view illustrating a coupling state before coupling the stage device of the side track buffer according to an embodiment of the present invention.

### DETAILED DESCRIPTION OF THE PREFERRED EMBODIMENTS

Hereinafter, a preferred embodiment of the present invention will be described in more detail with reference to the attached drawings.

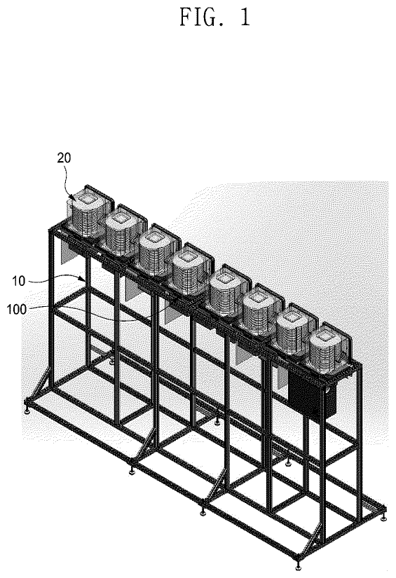

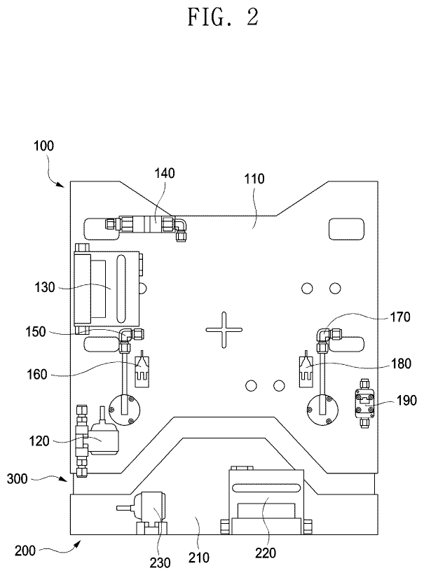

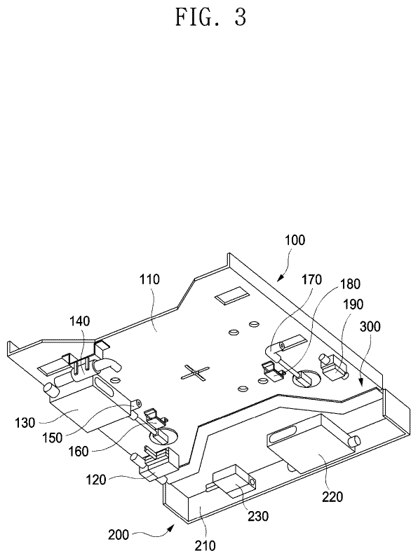

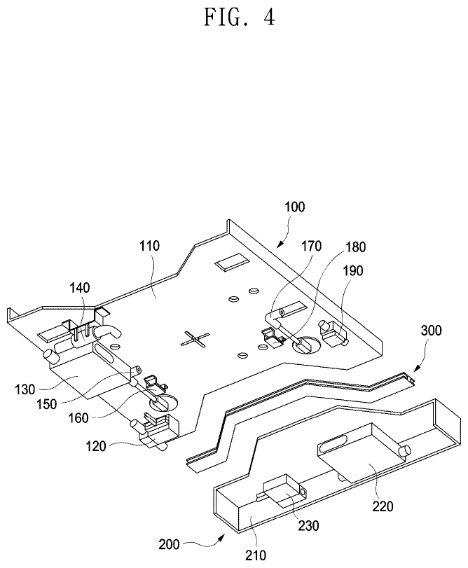

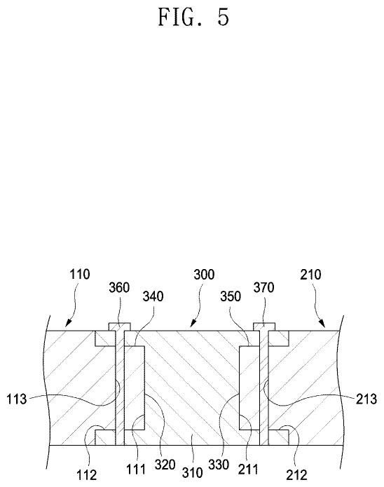

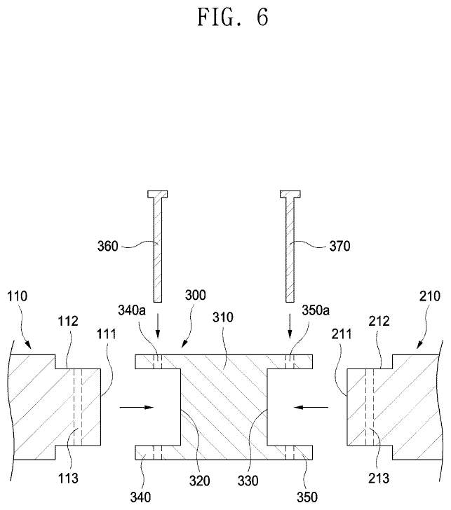

FIG. 1 is a view illustrating a configuration of a typical semiconductor process device, FIG. 2 is a view illustrating a configuration of a stage device of a side track buffer according to an embodiment of the present invention, FIG. 3 is a perspective view illustrating the stage device of the side track buffer according to an embodiment of the present invention, FIG. 4 is an exploded perspective view illustrating the stage device of the side track buffer according to an embodiment of the present invention, FIG. 5 is a view illustrating a coupling state after coupling the stage device of the side track buffer according to an embodiment of the present invention, and FIG. 6 is a view illustrating a coupling state before coupling the stage device of the side track buffer according to an embodiment of the present invention.

As illustrated in FIGS. 1 to 4, a stage device of a side track buffer according to the present embodiment is a stage device of a side track buffer, which is provided as a first module unit 100 including a first base 110, a supply part 120, a first flow control part 130, a filter part 140, a supply tube part 150, a first sensor part 160, a discharge part 170, a second sensor part 180, and a detection part 190 and allows an inert gas to flow through an inlet and an outlet of a stage installed on a side track buffer (STB) 10 provided with a shelf mounted on a rail of an overhead hoist transport (OHT) to support a front opening unified pod (FOUP) 20.

The base 110 is a base plate installed in a semiconductor process facility such as the side track buffer 10, and a plurality of guide protrusions are disposed on a top surface of the first base 110 to guide a coupling position of the FOUP 20 when the FOUP 20 is seated on the first base 110.

A first protrusion piece 111 detachably connected to a second base 210, a first seating groove 112 recessed in each of upper and lower portions of the first protrusion piece 111, and a first connection hole 113 vertically passing through the first protrusion piece 111 are provided at one end of the first base 110.

The supply part 120 is a supply member that is installed at one side of the first base of the first module unit 100 to supply the inert gas and is provided as an ON/OFF valve that opens and closes a passage through which the inert gas is supplied.

The first flow control part 130 is a flow control member that is installed at one side of the supply part 120 to control a flow rate of the inert gas and is provided as a flowmeter that measures a flow rate so that the flow rate of the inert gas is constant.

The flowmeter is constituted by an orifice and a diaphragm-type differential pressure gauge. In the case of the diaphragm-type differential pressure gauge, there is no flow through the differential pressure gauge, and a flow rate is measured by detecting a change in shape of the diaphragm according to a change in differential pressure at both sides.

The orifices and the differential pressure gauges have minimal influence on the process gas as it passes therethrough to ensure a long-term use.

In addition, when the orifice is connected to the supply tube part 150, a differential pressure may occur at front and rear ends of the orifice, and the differential pressure is changed according to the change in flow rate, and when measuring the differential pressure, a flow rate of a nitrogen gas and the process gas flowing through the supply tube part 150 may be measured.

The filter part 140 is a filter member that is connected to the first flow control part 130 to filter the inert gas, and a filter that filters foreign substances contained in the inert gas such as the nitrogen gas is provided in the passage of the supply tube part 150.

The supply tube part 150 is a tube member that is connected to the filter part 140 to supply the inert gas and supplies the inert gas so that the inert gas flows through the inlet and outlet of the semiconductor process facility.

The first sensor part 160 is a sensor member installed at one side of the first base 110 of the first module unit 100 to detect setting of the FOUP. The first sensor part 160 is provided as a detection sensor installed at one side of a top surface of the first base 110 to detect that the FOUP 20 is stored in a shelf.

The discharge part 170 is a tube member installed at the other side of the first base 110 of the first module unit 100 to discharge the inert gas and thus discharges the inert gas so that the inert gas flows through the inlet and the outlet of the semiconductor process facility.

The second sensor part 180 is a sensor member installed at the other side of the first base 110 of the first module unit 100 to detect setting of the FOUP. The first sensor part 160 is provided as a detection sensor installed at the other side of a top surface of the first base 110 to detect that the FOUP 20 is stored in the shelf.

The detection part 190 is a detection member installed at one side of the discharge part 170 to detect a temperature of the inert gas discharged from the process facility and humidity of the semiconductor process facility and is constituted by a sensor housing, an inlet, an outlet, a leak prevention ring, a sensor module, and a sensor cover.

The sensor housing is a housing member installed upstream of the discharge part 170 so that the inert gas discharged from the process facility passes therethrough and is provided as a housing having a communication path so that the inert gas discharged from the process facility is detected while passing therethrough.

The inlet is an inlet portion installed at one side of the sensor housing so that the inert gas discharged from the process facility is injected and is provided as an inlet of the communication path so that the inert gas discharged from the process facility is detected while passing therethrough.

The outlet is an outlet portion installed at the other side of the sensor housing so that the inert gas discharged from the process facility is discharged by passing through the sensor module and is provided as an outlet of the communication path so that the inert gas discharged from the process facility is detected while passing therethrough.

The leak prevention ring is a leak prevention member that is installed at a lower side of the sensor housing to prevent the inert gas discharged from the process facility from leaking to the outside and is installed at a lower portion of the sensor housing to maintain airtightness, thereby preventing the inert gas discharged from the process facility from leaking to the outside.

The sensor module is a module provided with a temperature sensor and a humidity sensor, which detect the temperature and humidity of the inert gas discharged to the discharge part 170 in real time and is provided as a sensor module that is formed into a board to prevent current from leaking in the temperature sensor and the humidity sensor.

The sensor cover is a leak prevention unit that is installed at an upper side of the sensor housing to cover the sensor module and prevent the inert gas discharged from the process facility from leaking to the outside and is configured to cover an upper portion of the sensor housing.

In the detection part 190, the humidity sensor produced as a semiconductor chip is formed into a board to prevent leakage from occurring and then is built into a housing block in which the leaking of the inert gas does not occur, and thus, the block in which the leaking does not occur accurately reads the humidity in the tube, in which a flow occurs, in real time to maintain the humidity having a constant level on the basis of the data.

In addition, the stage device of the side track buffer according to the present invention may further include a second module unit 200 that is detachably installed at one side of the first module unit 100 to control the discharge of the inert gas.

The second module 200 is a module member installed at one side of the first module 100 to control the discharge of the inert gas and includes a second base 210, a second flow control part 220, and a second discharge control part 230.

The second base 210 is a base plate that is coupled to one end of the first base of the first module 100. A plurality of guide protrusions are provided on a top surface of the second base 210 to guide a coupling position when the FOUP 20 is seated on the second base 210.

A second protrusion piece 211 detachably connected to the second base 210, a second seating groove 212 recessed in each of upper and lower portions of the second protrusion piece 211, and a second connection hole 213 vertically passing through the second protrusion piece 211 are provided at one end of the second base 210.

The second flow control part 220 is a flow control member that is installed at one side of the second base 210 to control a discharge amount of inert gas and is provided as a flowmeter that measures a discharge amount so that the discharge amount of inert gas is constant.

The flowmeter is constituted by an orifice and a diaphragm-type differential pressure gauge. In the case of the diaphragm-type differential pressure gauge, there is no flow through the differential pressure gauge, and a flow rate is measured by detecting a change in shape of the diaphragm according to a change in differential pressure at both sides. The orifices and the differential pressure gauges have minimal influence on the process gas as it passes therethrough to ensure a long-term use.

In addition, when the orifice is connected to the discharge part 170, a differential pressure occurs between front and rear ends of the orifice, and the differential pressure is changed according to a change in flow rate. Thus, when the change in flow rate is measured, flow rates of the nitrogen gas and the process gas discharged through the discharge part 170 may be measured.

The second discharge control part 230 is a discharge control member installed at the other side of the second base 210 to control whether to discharge the inert gas and is provided as an ON/OFF valve that opens and closes the passage through which the inert gas is discharged.

In addition, the stage device of the side track buffer according to the present invention may further include the connection unit 300 installed between the first module unit 100 and the second module unit 200 to connect and couple the first base 110 to the second base 210.

The connection unit 300 is a connecting member installed between the first module unit 100 and the second module unit 200 to detachably connect the first base 110 to the second base 210 and is constituted by a connection piece 310, a first connection groove 320, a second connection groove 330, a first connection protrusion 340, a second connection protrusion 350, a first fixing piece 360, and a second fixing piece 370 as illustrated in FIGS. 5 and 6.

The connection piece 310 is a connection member that connects the first base 110 to the second base 210 so that the first base 110 and the second base 210 are attached to and detached from each other and is provided as a connection plate having the same thickness as each of the first base 110 and the second base 210.

The first connection groove 320 is a groove member that is recessed in one end of the connection piece 310 and coupled to the first base 110 and is installed so that the first protrusion piece 111 of the first base 110 is fitted to be coupled so as to be attached to and detached from each other.

The second connection groove 330 is a groove member that is recessed in the other end of the connection piece 310 and coupled to the second base 210 and is installed so that the second protrusion piece 211 of the second base 210 is fitted to be coupled so as to be attached to and detached from each other.

The first connection protrusion 340 is a protrusion member that protrudes upward and downward from one end of the connection pieces 310 so as to be coupled to the first base 110 and is fitted to be coupled to the first seating groove 112 of the first base 110 so as to be attached to and detached from each other, and a first fixing hole 340a vertically passes through the first connection protrusion 340.

The second connection protrusion 350 is a protrusion member that protrudes upward and downward from the other end of the connection pieces 310 so as to be coupled to the second base 210 and is fitted to be coupled to the second seating groove 212 of the second base 210 so as to be attached to and detached from each other, and a second fixing hole 350a vertically passes through the second connection protrusion 350.

The first fixing piece 360 is a fixing member installed to be coupled to the first fixing hole 340a of the first connection protrusion 340 to fix the first base 110 and the connection piece 310 and is provided as a coupling fixing member such as a bolt or piece that fixes the first base 110 and the connection piece 310 so as to be attached to and detached from each other.

The second fixing piece 370 is a fixing member installed to be coupled to the second fixing hole 350a of the second connection protrusion 350 to fix the second base 210 and the connection piece 310 and is provided as a coupling fixing member such as a bolt or piece that fixes the second base 210 and the connection piece 310 so as to be attached to and detached from each other.

In addition, the present invention may provide the semiconductor process device that supports the front opening unified pod (FOUP) such as the side track buffer (STB) provided with the stage device of the side track buffer according to the present embodiment.

As described above, the present invention provides may provide the effect of improving the productivity and the process performance of the semiconductor process device by detecting the temperature of the inert gas discharged from the semiconductor process device and the humidity of the semiconductor process facility to individually control the inflow and discharge amount of inert gas in the plurality of semiconductor process devices.

In addition, the present invention may provide the effect of improving the semiconductor production yield by detachably installing the second module unit as the variable discharge module to the second module unit to individually control the discharge mount of inert gas injected into the FOUP through the supply nozzle of the semiconductor process device such as the STB for each FOUP to improve the semiconductor production yield.

In addition, the present invention may provide the effect of including the second base, the second flow control part, and the second discharge control part as the second module unit to detachably install the second module unit of the variable discharge module to control the discharge amount of inert gas according to the injection amount of inert gas in the second module unit and individually control the discharge amount of inert gas by receiving the electronic signal when injecting the different amounts of inert gas for each FOUP at the flow rate of about 5 slm to about 50 slm.

In addition, the present invention may provide the effect of including the connection piece, the connection groove, and the connection protrusion as the connection unit to attach and detach the variable discharge module by using the connection unit of the joint block, thereby individually controlling the flow rate of the gas in the plurality of FOUPs.

As described above, the present invention provides may provide the effect of improving the productivity and the process performance of the semiconductor process device by detecting the temperature of the inert gas discharged from the semiconductor process device and the humidity of the semiconductor process facility to individually control the inflow and discharge amount of inert gas in the plurality of semiconductor process devices to improve the production performance and the process performance in the semiconductor process devices.

In addition, the present invention may provide the effect of improving the semiconductor production yield by detachably installing the second module unit as the variable discharge module to the second module unit to individually control the discharge mount of inert gas injected into the FOUP through the supply nozzle of the semiconductor process device such as the STB for each FOUP to improve the semiconductor production yield.

In addition, the present invention may provide the effect of including the second base, the second flow control part, and the second discharge control part as the second module unit to detachably install the second module unit of the variable discharge module to control the discharge amount of inert gas according to the injection amount of inert gas in the second module unit and individually control the discharge amount of inert gas by receiving the electronic signal when injecting the different amounts of inert gas for each FOUP at the flow rate of about 5 slm to about 50 slm.

In addition, the present invention may provide the effect of including the connection piece, the connection groove, and the connection protrusion as the connection unit to attach and detach the variable discharge module by using the connection unit of the joint block, thereby individually controlling the flow rate of the gas in the plurality of FOUPs.

The foregoing present invention may be carried out in various embodiments without departing from the technical ideas or primary features. Therefore, the above-described embodiments are merely illustrative of the present invention, but should not be limitedly interpreted.

### DESCRIPTION OF THE SYMBOLS

100: First module unit
200: Connection unit
300: Second module unit

What is claimed is:

1. A stage device of a side track buffer, which allows an inert gas to flow through the side track buffer, the stage device comprising:
a supply part (120) installed at one side of a first base of a first module unit (100) to supply the inert gas;
a first flow control part (130) installed at one side of the supply part (120) to control a flow rate of the inert gas;
a filter part (140) connected to the first flow control part (130) to filter the inert gas; and
a discharge part (170) installed at the other side of the first base of the first module unit (100) to discharge the inert gas.

2. The stage device of claim 1, further comprising a second module unit (200) detachably installed at one side of the first module unit (100) to control the discharge of the inert gas.

3. The stage device of claim 2, wherein the second module unit (200) comprises:
a second base coupled to one end of the first base of the first module unit (100);
a second flow control part installed at one side of the second base to control a discharge amount of inert gas; and
a second discharge control part installed at the other side of the second base to control whether to discharge the inert gas.

4. The stage device of claim 2, further comprising a connection unit (300) installed between the first module unit (100) and the second module unit (200) to connect the first base to the second base so as to be attached to and detached from each other.

5. The stage device of claim 4, wherein the connection unit (300) comprises:
a connection piece configured to couple and connect the first base to the second base;
a first connection groove which is recessed in one end of the connection piece and to which the first base is coupled;
a second connection groove which is recessed in the other end of the connection piece and to which the second base is coupled;
a first connection protrusion protruding from one end of the connection piece and coupled to the first base; and
a second connection protrusion protruding from the other end of the connection piece and coupled to the second base.

6. The stage device of claim 5, wherein the connection unit (300) further comprises:
a first fixing piece installed to be coupled to the first connection protrusion to fix the first base and the connection piece; and
a second fixing piece installed to be coupled to the second connection protrusion to fix the second base and the connection piece.

7. A semiconductor process device provided with the stage device of the side track buffer as set forth in claim 1.
